(19) United States
(12) Patent Application Publication
(10) Pub. No.: US 2025/0107415 A1
(43) Pub. Date: Mar. 27, 2025

(54) DISPLAY DEVICE

(71) Applicant: Samsung Display Co., LTD., Yongin-si (KR)

(72) Inventors: HYUNBAE PARK, Yongin-si (KR); Seung Hui SEO, Yongin-si (KR); Hyelynn SONG, Yongin-si (KR); Tae Woo LIM, Yongin-si (KR); Moon-Keun CHOI, Yongin-si (KR)

(21) Appl. No.: 18/680,802

(22) Filed: May 31, 2024

(30) Foreign Application Priority Data
Sep. 25, 2023 (KR) 10-2023-0128595

(51) Int. Cl. H10K 59/80; H10K 59/122

(52) U.S. Cl. CPC H10K 59/8791; H10K 59/122

(57) ABSTRACT

A display device includes: a display device having a plurality of light emitting areas and a non-light emitting area between adjacent light emitting areas of the plurality of light emitting areas, and a color conversion part overlapping with the display device, wherein the color conversion part includes: a first substrate including a first surface facing the display device, and a color filter layer on the first surface of the first substrate and including a plurality of color filters, and wherein the color filter layer has a color filter opening where the color filter layer is removed at at least a portion of the non-light emitting area.

### CROSS-REFERENCE TO RELATED APPLICATION

The present application claims priority to and the benefit of Korean Patent Application No. 10-2023-0128595, filed on Sep. 25, 2023, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

A light emitting device is a device that emits light when an exciton is formed by the combination of a hole supplied from an anode and an electron supplied from a cathode within a light emitting layer formed between the anode and the cathode, and the exciton is stabilized.

Light emitting devices may have various advantages such as relatively wide viewing angles, relatively fast response speeds, thinness, and low power consumption, so they may be widely applied to various electrical and electronic devices such as televisions, monitors, and mobile phones.

A display device including a color conversion layer may be utilized to implement a highly efficient display device. The color conversion layer can convert incident light into a different color.

The above information disclosed in this Background section is only for enhancement of understanding of the background and therefore the information discussed in this Background section does not necessarily constitute prior art.

### SUMMARY

Aspects of some embodiments may relatively improve display quality by reducing external light reflectance on the display device.

A display device according to some embodiments includes a display device having a plurality of light emitting areas and a non-light emitting area between adjacent light emitting areas, and a color conversion part overlapping the display device, wherein the color conversion part comprises a first substrate including a first surface facing the display device, and a color filter layer on the first surface of the first substrate and including a plurality of color filters, the color filter layer on the first surface of the first substrate and including a plurality of color filters, and wherein the color filter layer has a color filter opening where the color filter layer is removed at at least a portion of the non-light emitting area.

According to some embodiments, the color conversion part further includes a bank layer between the first substrate and the display device, and the bank layer may have an opening corresponding to the light emitting area.

According to some embodiments, the bank layer may contact the first surface of the first substrate through the color filter opening.

According to some embodiments, at least two of the plurality of color filters may overlap each other in the non-light emitting area to form an overlapping part.

According to some embodiments, the color filter opening may be defined by an edge of the overlapping part.

According to some embodiments, the bank layer includes a first bank part that overlaps the overlapping part and a second bank part that does not overlap the overlapping part, and the second bank part contacts the first surface of the first substrate in the non-light emitting area.

According to some embodiments, it may further include a filling layer between the bank layer and the display device.

According to some embodiments, the bank layer may be removed from the non-light emitting area to form a bank opening.

According to some embodiments, it may further include a filling layer positioned between the first substrate and the display device, and the filling layer may be in contact with the first surface of the first substrate through the bank opening.

According to some embodiments, the filling layer includes a first filling part overlapping the light emitting area and a second filling part overlapping the non-light emitting area, and the second filling part may be in contact with the first surface of the first substrate.

According to some embodiments, the display device includes a second substrate, a plurality of light emitting devices on the second substrate, and an encapsulation part on the light emitting devices, the bank layer is formed on the encapsulation part, and a filling layer between the bank layer and the first substrate can be further included.

According to some embodiments, the filling layer may contact the first surface of the first substrate through the color filter opening.

According to some embodiments, at least two of the plurality of color filters may overlap in the non-light emitting area to form an overlapping part, and the color filter opening may be defined by an edge of the overlapping part.

According to some embodiments, the filling layer includes a first filling part overlapping the light emitting area and a second filling part overlapping the non-light emitting area, and the second filling part may be in contact with the first surface of the first substrate.

According to some embodiments, at least two of the plurality of color filters may overlap in the non-light emitting area to form an overlapping part, and may further include a light blocking layer overlapping the overlapping part and positioned between the color filter layer and the first substrate.

A display device according to some embodiments includes a display device having a plurality of light emitting areas and a non-light emitting area between adjacent light emitting areas, a color conversion part overlapping the display device, and a color conversion part between the display device and the color conversion unit and a filling layer, wherein the color conversion part includes a first substrate including a first surface facing the display device, and a bank layer between the first substrate and the display device, and the bank layer or the filling layer is in contact with the first surface of the first substrate.

According to some embodiments, the color conversion part may further include a color filter layer including a plurality of color filters on the first surface of the first substrate, and the color filter layer may have a color filter opening in the non-light emitting area.

According to some embodiments, the bank layer or the filling layer may contact the first surface of the first substrate through the color filter opening.

According to some embodiments, display quality can be relatively improved by reducing the external light reflectance of the display device.

### BRIEF DESCRIPTION OF DRAWINGS

FIG. 1 is a plan view of a display device according to some embodiments.

FIG. 2 is a cross-sectional view of a display device according to some embodiments.

FIG. 3 is a plan view of a display area of a display device according to some embodiments.

FIG. 4 is a cross-sectional view of a display area of a display device according to some embodiments.

FIG. 5 is an enlarged view of a portion of the cross-sectional view of the display device shown in FIG. 4.

FIG. 6 is a cross-sectional view of a display area of a display device according to some embodiments.

FIG. 7 is an enlarged view of a portion of the cross-sectional view of the display device shown in FIG. 6.

FIG. 8 is a cross-sectional view of a display area of a display device according to some embodiments.

FIG. 9 is a cross-sectional view of a display area of a display device according to some embodiments.

### DETAILED DESCRIPTION

Hereinafter, with reference to the attached drawings, aspects of some embodiments of the present invention will be described in more detail so that those skilled in the art can relatively easily implement the present invention.

The invention may be implemented in many different forms and is not limited to the embodiments described herein.

In order to more clearly explain aspects of some embodiments of the present invention, parts that are not relevant to the description are omitted, and identical or similar components are assigned the same reference numerals throughout the specification.

In addition, the size and thickness of each component shown in the drawings are shown arbitrarily for convenience of explanation, so the present invention is not necessarily limited to that which is shown.

In the drawing, the thickness is enlarged to clearly express various layers and areas.

And in the drawings, for convenience of explanation, the thicknesses of some layers and regions are exaggerated.

Additionally, when a part of a layer, membrane, region or plate is said to be “above” or “on” another part, this includes not only cases where it is “directly above” another part, but also cases where there is another part in between.

Conversely, when a part is said to be “right on top” of another part, it means that there is no other part in between.

In addition, being “above” or “on” a reference part means being located above or below the reference part, and does not necessarily mean being located “above” or “on” it in the direction opposite to gravity.

In addition, throughout the specification, when a part is said to “include” a certain component, this means that it may further include other components rather than excluding other components, unless specifically stated to the contrary.

In addition, throughout the specification, when reference is made to “on a plane,” this means when the target portion is viewed from above, and when reference is made to “in cross-section,” this means when a cross-section of the target portion is cut vertically and viewed from the side.

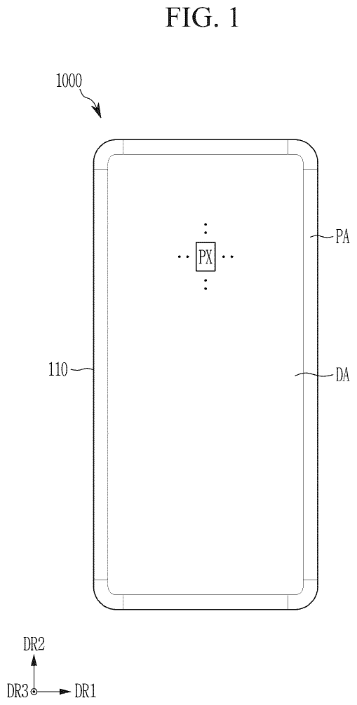

The structure of a display device according to some embodiments will be described in more detail with reference to FIG. 1 to FIG. 5.

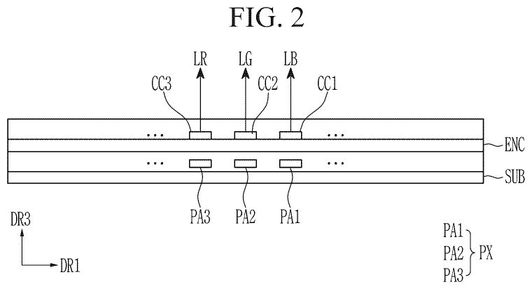

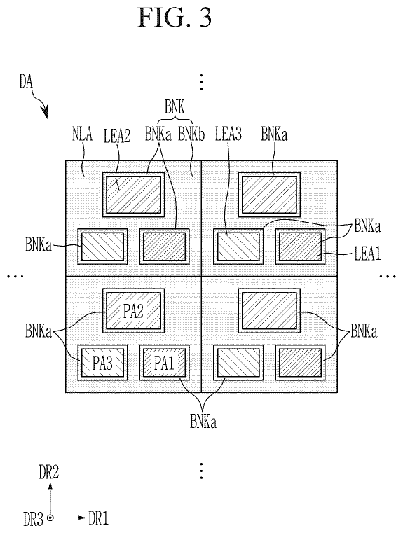

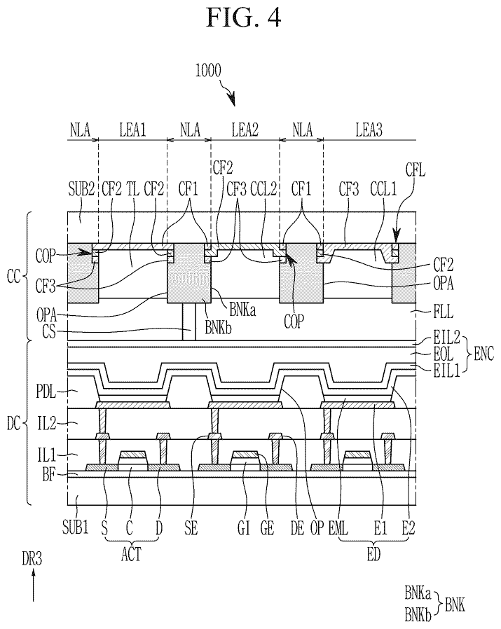

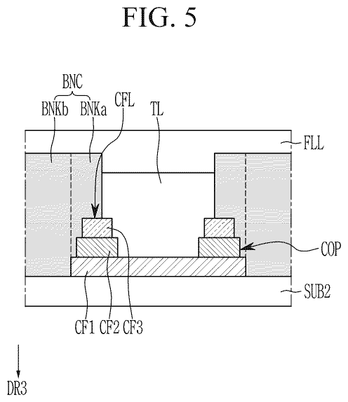

FIG. 1 is a plan view of a display device according to some embodiments, FIG. 2 is a cross-sectional view of a display device according to some embodiments, FIG. 3 is a plan view of a display area of a display device according to some embodiments, and FIG. 4 is a cross-sectional view of the display area of a display device according to some embodiments, and FIG. 5 is an enlarged view of a portion of the cross-sectional view of the display device shown in FIG. 4.

Referring to FIG. 1, the display device 1000 according to some embodiments includes a display panel 110 including a display area DA capable of displaying images and a peripheral area PA around (e.g., in a periphery or outside a footprint of) the display area DA.

The display area DA includes a plurality of pixels PX that are units for displaying an image, and the peripheral area PA may or may not display images.

The peripheral area PA may surround the display area DA, but embodiments according to the present disclosure are not limited thereto.

The display area DA may have a display surface parallel to a first direction DR1 and a second direction DR2.

The normal direction of the display surface on which an image is displayed—that is, the thickness direction of the display panel 110—may be parallel to a third direction DR3.

The display panel 110 may be a rigid display panel, but it is not limited thereto and may be a flexible display panel.

The display panel 110 may be a light emitting display panel, but the type of the display panel 110 is not limited thereto and may be of various types.

For example, the display panel 110 may include a micro-light emitting diode display panel, a quantum dot light emitting diode display panel, a quantum dot organic light emitting diode display panel, etc.

Referring to FIG. 1 and FIG. 2, a display panel 110 according to some embodiments includes at least one substrate SUB, and a plurality of pixels PX can be formed on the substrate SUB corresponding to the display area DA of FIG. 1.

The plurality of pixels PX may include a first pixel PA1, a second pixel PA2, and a third pixel PA3, which may display different colors.

Each pixel PX may include at least one transistor and a light emitting device connected thereto.

An encapsulation part ENC may be located on the plurality of pixels (PX).

The encapsulation part ENC can cover a light emitting device ED and protect the light emitting device ED from external air or moisture.

The encapsulation part ENC may overlap the front surface of the display area DA in the direction in which the image is displayed, and may be partially located on the peripheral area PA.

A first color conversion part CC1, a second color conversion part CC2, and a transmission part CC3 may be located on the encapsulation part ENC.

The first color conversion part CC1 overlaps the first pixel PA1, the second color conversion part CC2 overlaps the second pixel PA2, and the transmission part CC3 overlaps the third pixel PA3.

Light emitted from the first pixel PA1 may pass through the first color conversion part CC1 to provide a first color light LB.

Light emitted from the second pixel PA2 may pass through the second color conversion part CC2 to provide a second color light LG.

Light emitted from the third pixel PA3 may pass through the transmission part CC3 to provide a third color light LR.

For example, the first color light LB may be blue light, the second color light LG may be green light, and the third color light LR may be red light, but the displayed colors are not limited to these.

Referring to FIG. 2 and FIG. 3, the display area DA according to some embodiments may include a plurality of light emitting areas corresponding to a plurality of pixels PX.

For example, it may include a first light emitting area LEA1 corresponding to the first pixel PA1, a second light emitting area LEA2 corresponding to the second pixel PA2, and a third light emitting area LEA3 corresponding to the third pixel PA3.

In the display area DA, a non-light emitting area NLA may be located between the first light emitting area LEA1, the second light emitting area LEA2, and the third light emitting area LEA3.

Each light emitting area LEA1, LEA2, LEA3 is shown as a square in a plan view, but may have other shapes such as a rhombus, pentagon, or octagon, and may have various shapes and areas depending on the embodiment.

Referring to FIG. 3 and FIG. 4, a bank layer BNK may be located in at least a portion of the non-light emitting area NLA, and the bank layer BNK may be removed from each light emitting area LEA1, LEA2, LEA3 to form an opening OPA.

Each light emitting area LEA1, LEA2, LEA3 may be located corresponding to each opening OPA.

The bank layer BNK may include an organic material such as acrylic resin.

The bank layer BNK may include a light absorbing material that absorbs a visible light wavelength band.

According to some embodiments, the bank layer BNK may include an organic light blocking material and serve as a light blocking layer, and may serve as a barrier rib.

Referring to FIG. 4, the display device 1000 according to some embodiments may include a display device DC and a color conversion part CC in a cross-sectional structure.

The display device DC may include a first substrate SUB1 and a plurality of transistors, and a plurality of light emitting devices formed thereon.

The first substrate SUB1 includes an insulating material and may include a transparent material.

For example, the first substrate SUB1 may include glass, quartz, or a plastic such as polyimide.

The first substrate SUB1 may be a rigid substrate or may have flexible characteristics that can be curved, bent, folded, or rolled.

A buffer layer BF may be located on the first substrate SUB1.

The buffer layer BF may include an inorganic insulating material or an organic insulating material including silicon oxide (SiOx), silicon nitride (SiNx), silicon oxynitride (SiOxNy), etc., and may be a single layer or a multilayer.

A semiconductor layer ACT may be located on the buffer layer BF.

The semiconductor layer ACT may include a semiconductor material such as amorphous silicon, polycrystalline silicon, or an oxide semiconductor.

The semiconductor layer ACT may include a channel region (C), a source region(S), and a drain region (D).

The source region(S) and drain region (D) may be located on both sides of the channel region (C), respectively.

The channel region (C) is an intrinsic semiconductor that is not doped with impurities, and the source region(S) and drain region (D) are impurity semiconductors that are doped with conductive impurities and may have conductivity.

A gate insulating layer (GI) may be located on the semiconductor layer ACT.

The gate insulating layer GI may include an inorganic or organic insulating material including silicon oxide (SiOx), silicon nitride (SiNx), or silicon oxynitride (SiOxNy), and may be a single layer or a multilayer.

A first conductive layer including a gate electrode GE may be positioned on the gate insulating layer (GI).

The first conductive layer is aluminum (AI), platinum (Pt), palladium (Pd), silver (Ag), magnesium (Mg), gold (Au), nickel (Ni), neodymium (Nd), or iridium (Ir), it may contain at least one metal or alloy of metals such as chromium (Cr), nickel (Ni), calcium (Ca), molybdenum (Mo), titanium (Ti), tungsten (W), and copper (Cu), and it may be a single layer or multiple layers.

An interlayer insulating layer IL1 may be positioned on the gate electrode GE.

The interlayer insulating layer IL1 may include an inorganic or organic insulating material including silicon oxide (SiOx), silicon nitride (SiNx), or silicon oxynitride (SiOxNy), and may be a single layer or a multilayer.

A second conductive layer including a source electrode SE and a drain electrode DE may be positioned on the interlayer insulating layer IL1.

The source electrode SE and the drain electrode DE may be electrically connected to the source region S and the drain region D of the semiconductor layer ACT, respectively, through contact holes formed in the interlayer insulating layer IL1.

A protective layer IL2 may be positioned on the interlayer insulating layer IL1, the source electrode SE, and the drain electrode DE.

The protective layer IL2 may cover and planarize the interlayer insulating layer IL1, the source electrode SE, and the drain electrode DE.

The protective layer IL2 may include an organic or inorganic insulating material such as a polymer derivative, acrylic polymer, imide polymer, polyimide, polyamide, acrylic polymer, or siloxane polymer.

A third conductive layer including a first electrode E1 may be positioned on the protective layer IL2.

The first electrode E1 may be electrically connected to the drain electrode DE through a contact hole in the protective layer IL2.

The driving transistor, consisting of a gate electrode GE, a semiconductor layer ACT, a source electrode SE, and a drain electrode DE, can be electrically connected to the first electrode E1 to supply a drive current to the light emitting device ED to be described later.

In addition to the driving transistor. the display device according to some embodiments may further include a switching transistor connected to the data line and transmit data voltage in response to the scan signal, and a compensation transistor connected to the driving transistor, compensating for the threshold voltage of the driving transistor in response to the scan signal.

A pixel insulating layer PDL may be positioned on the protective layer IL2 and the first electrode E1.

The pixel insulating layer PDL may have a pixel opening OP that overlaps the first electrode E1 and defines a light emitting area.

The pixel insulating layer PDL may include an organic insulating material such as polyimide, polyamide, acrylic resin, benzocyclobutene, or phenol resin, or a silica-based inorganic insulating material.

A light emitting layer EML may be positioned on the first electrode E1 overlapping the pixel opening OP.

The light emitting layer EML may include a low-molecular weight organic material or a high-molecular weight organic material such as poly 3,4-ethylenedioxythiophene PEDOT.

The light emitting layer EML may include one or more of a hole injection layer HIL, a hole transport layer HTL, an electron transport layer ETL, and an electron injection layer EIL, and it may be a multilayer.

The light emitting layer EML may be located mostly within the pixel opening OP, and may also include a portion located on the side of or above the pixel insulating layer PDL.

The second electrode E2 may be located on the light emitting layer EML.

The second electrode E2 may be formed of a single conductor across the plurality of pixels PX.

The first electrode E1, the light emitting layer EML, and the second electrode E2 may together form the light emitting device ED.

The first electrode E1 may be an anode, which is a hole injection electrode, and the second electrode E2 may be a cathode, which is an electron injection electrode.

However, the embodiments according to the present disclosure are not necessarily limited to this, and the first electrode E1 may be a cathode and the second electrode E2 may be an anode depending on the driving method of the display device.

Holes and electrons are injected into the light emitting layer EML from the first electrode E1 and the second electrode E2, respectively, and light emission occurs when the excitons combined with the injected holes and electrons fall from the excited state to the ground state.

An encapsulation part ENC may be located on the second electrode E2.

The encapsulation part ENC covers and seals the light emitting element ED, thereby blocking the inflow of external moisture and oxygen.

The encapsulation part ENC may include a plurality of layers and may be formed of a composite film including inorganic and organic films alternately stacked.

For example, the encapsulation part ENC may include an inorganic layer EIL1, an organic layer EOL, and an inorganic layer EIL2 formed sequentially.

A color conversion part CC may be located on the encapsulation part ENC.

The color conversion part CC may include a second substrate SUB2 that is parallel to and overlaps a first substrate SUB1.

The second substrate SUB2 includes an insulating material and may include a transparent material.

For example, the first substrate SUB1 may include glass, quartz, or a plastic such as polyimide.

The first substrate SUB1 may be a rigid substrate or may have flexible characteristics that can be curved, bent, folded, or rolled.

The color conversion part CC may include a first color filter CF1, a second color filter CF2, and a third color filter CF3 located between the second substrate SUB2 and the display device DC.

A color filter layer includes the first color filter CF1, the second color filter CF2, and the third color filter CF3.

According to some embodiments, the first color filter CF1, the second color filter CF2, and the third color filter CF3 may be formed under the lower surface of the second substrate SUB2.

The third color filter CF3 may overlap the first conversion layer CCL1, which will be described later.

The third color filter CF3 may transmit the third color light that has passed through a first color conversion layer CCL1 and absorb light of the remaining wavelengths, thereby increasing the purity of the third color light emitted to the outside of the display device.

The third color light may be red.

The second color filter CF2 may overlap a second color conversion layer CCL2.

The second color filter CF2 may transmit the second color light that has passed through a second color conversion layer CCL2 and absorb light of the remaining wavelengths, thereby increasing the purity of the second color light emitted to the outside of the display device.

The second color light may be green.

The first color filter CF1 may overlap with the transmission layer TL, which will be described later.

The first color filter CF1 can transmit the first color light that has passed through the transmission layer TL and absorb light of the remaining wavelengths, thereby increasing the purity of the first color light emitted to the outside of the display device.

The first color light may be blue.

Referring to FIG. 4 and FIG. 5, the color filter layer including the first color filter CF1, the second color filter CF2, and the third color filter CF3 is removed at at least a portion of the non-light emitting area NLA to have a color filter opening COP.

The color filter opening COP may have an edge that can be located in the non-light emitting area NLA or at the boundary between the non-light emitting area NLA and the light emitting areas LEA1, LEA2, and LEA3.

FIG. 4 and FIG. 5 show an example in which the edge of the color filter opening COP is located within the non-light emitting area NLA.

At least two of the first color filter CF1, the second color filter CF2, and the third color filter CF3 are used in a portion of the non-light emitting area NLA adjacent to an opening OPA of the bank layer BNK. They may overlap to form an overlapping part CFL, and the overlapping part CFL may function as a light blocking layer.

The overlapping part CFL may be located around the edge of the opening OPA and may be located corresponding to the non-light emitting area NLA.

If an overlapping part CFL exists, the color filter opening COP may be defined by an edge of the overlapping part CFL.

The overlapping part CFL may be omitted.

When the overlapping part CFL is omitted, the color filter opening COP may be substantially aligned with the boundary between the non-light emitting area NLA and the light emitting areas LEA1, LEA2, and LEA3.

The non-light emitting area NLA may overlap the pixel insulating layer PDL of the display device DC.

In a cross-sectional view, the bank layer BNK is located between the first color filter CF1, the second color filter CF2, and the third color filter CF3, the second substrate SUB2, and the display device DC.

The bank layer BNK may have an opening OPA that overlaps the pixel opening OP.

The opening OPA may correspond to the light emitting area LEA1, LEA2, and LEA3 of each pixel.

The bank layer BNK may overlap the pixel insulating layer PDL of the display device DC.

The opening OPA includes the transmission layer TL corresponding to the first light emitting area LEA1, the second color conversion layer CCL2 corresponding to the second light emitting area LEA2, the third light emitting area LEA3, and the first color conversion layer CCL1.

The first color conversion layer CCL1 can convert supplied light into the third color light.

The first color conversion layer CCL1 may include quantum dots.

The second color conversion layer CCL2 can convert supplied light into the second color light.

The second color conversion layer CCL2 may include quantum dots.

In this specification, quantum dots (hereinafter also referred to as semiconductor nanocrystals) include group II-VI compounds, group III-V compounds, group IV-VI compounds, group IV elements or compounds, group I-III-VI compounds, and it may include a group I-II-IV-VI compound, or a combination thereof.

According to some embodiments, quantum dots may have a core-shell structure including a core including a nanocrystal and a shell surrounding the core.

The shell of the quantum dots may serve as a protective layer to maintain semiconductor properties by preventing or reducing chemical denaturation of the core and/or as a charging layer to impart electrophoretic properties to the quantum dots.

The shell may be single layer or a multilayer.

The interface between the core and the shell may have a concentration gradient in which the concentration of elements present in the shell decreases toward the center.

Examples of the shell of quantum dots include metal or non-metal oxides, semiconductor compounds, or combinations thereof.

The interface between the core and the shell may have a concentration gradient in which the concentration of elements present in the shell decreases toward the center.

A semiconductor nanocrystal may have a structure including a single semiconductor nanocrystal core and a multi-layered shell surrounding it.

Quantum dots can control absorption/emission wavelengths by adjusting their composition and size.

The maximum emission peak wavelength of the quantum dots may range from ultraviolet to infrared wavelengths or longer.

The transmission layer TL may include a polymer resin and a scatterer included in the polymer resin, and may transmit light incident from the light emitting device ED.

The first color conversion layer CCL1 corresponding to the third light emitting area LEA3 can color-convert the incident light into third color light and emit it.

The second color conversion layer CCL2 corresponding to the second light emitting area LEA2 may convert incident light into second color light and emit it.

Light incident on the transmission layer TL corresponding to the first light emitting area LEA1 may be transmitted without being color-converted.

The incident light may include, for example, first color light.

In this case, the incident light may be blue light alone or a mixture of blue light and green light.

Incident light may include all blue light, all green light, and all red light.

A filling layer FLL may be positioned between the transmission layer TL, the first color conversion layer CCL1, the second color conversion layer CCL2, the bank layer BNK, and the display device DC.

The filling layer FLL is located between the color conversion part CC and the display device DC, and can combine them with each other.

The filling layer FLL may include a filler.

According to some embodiments, the position of the filling layer FLL may be filled with air.

A spacer CS may be located between the bank layer BNK and the encapsulation part ENC.

The spacer CS may be formed directly on the encapsulation part ENC or directly under the bank layer BNK.

The spacer CS can maintain the gap between the display device DC and the color conversion part CC.

Referring to FIG. 3 to FIG. 5, the bank layer BNK can come into contact with the surface of the second substrate SUB2—for example, the lower surface of the second substrate SUB2—through the color filter opening COP in the non-light emitting area NLA.

When the color filter layer including the first color filter CF1, the second color filter CF2, and the third color filter CF3 includes an overlapping part CFL, the bank layer BNK is connected to the overlapping part CFL, and it may include a first bank part BNKa that overlaps and a second bank part BNKb that does not overlap the overlapping part CFL.

The bank layer BNK is not physically separated into a first bank part BNKa and a second bank part BNKb, but may be named according to whether or not it overlaps with the overlapping part CFL.

The first bank part BNKa and the second bank part BNKb may be formed integrally.

If the overlapping part CFL is omitted, the first bank part BNKa may also be omitted.

The second bank part BNKb of the bank layer BNK may contact the second substrate SUB2 in most areas of the non-light emitting area NLA.

According to some embodiments, the color filter layer is removed from the non-light emitting area NLA, and the bank layer BNK contacts the second substrate SUB2, thereby reducing the external light reflectance at the bottom boundary of the second substrate SUB2, thereby relatively improving display quality.

According to a comparative example, the first color filter CF1, the second color filter CF2, and the third color filter CF3 do not include the color filter opening COP, so that the second substrate is formed even in the non-light emitting area NLA, when the lower surface of the second substrate SUB2 is in contact with the color filter layer, the reflectance between the lower surface of the second substrate SUB2 and the color filter layer is high, so the external light reflectance on the second substrate SUB2 side is approximately 0.38%, but according to some embodiments including the color filter opening COP, the external light reflectance measured under the same conditions as the comparative example is lowered to approximately 0.29%, and it can be confirmed that the external light reflectance is reduced by approximately 20% or more.

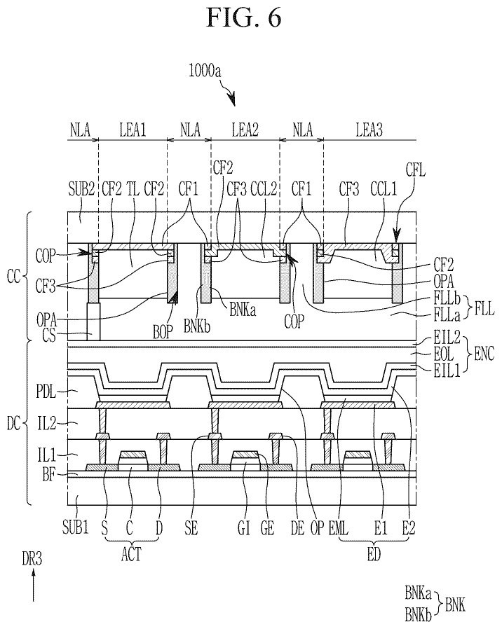

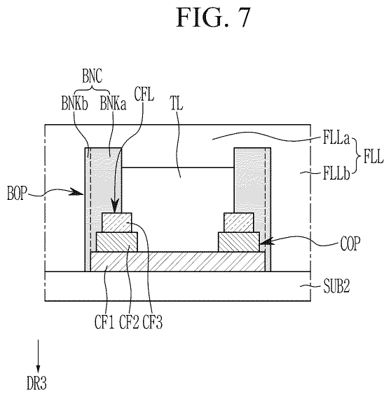

A display device according to some embodiments will be described in more detail with reference to FIG. 6 and FIG. 7 along with the previously described drawings.

FIG. 6 is a cross-sectional view of a display area of a display device according to some embodiments, and FIG. 7 is an enlarged view of a portion of the cross-sectional view of the display device shown in FIG. 6.

Referring to FIG. 6 and FIG. 7, a display device 1000a according to some embodiments is mostly the same as the display device 1000 according to the previously described embodiments, but the bank layer BNK is removed from the non-light emitting area NLA. to form a bank opening (BOP).

The bank layer BNK may include a first bank part BNKa that overlaps the overlapping part CFL of the color filter layer and a second bank part BNKb that does not overlap the overlapping part CFL.

The second bank part BNKb may be removed from at least a portion of the non-light emitting area NLA to form the bank opening BOP.

When the overlapping part CFL is omitted, the first bank part BNKa may be omitted.

In order to form the opening OPA, at least one of the first bank part BNKa or the second bank part BNKb may be left without being omitted.

In most areas of the non-light emitting area NLA, the filling layer FLL is connected to the surface of the second substrate SUB2—for example, the bottom surface of the second substrate SUB2—through the bank opening BOP of the bank layer BNK.

The filling layer FLL may be located between the second substrate SUB2 and the display device DC.

Referring to FIG. 6 and FIG. 7, the filling layer FLL includes the light emitting area LEA1, LEA2, LEA3, the bank layer BNK, the transmission layer TL, the first color conversion layer CCL1, or the second color conversion layer, a first filling part FLLa that overlaps the second color conversion layer CCL2 and a second filling part that does not overlap the second color conversion layer CCL2, overlaps the non-light emitting area NLA, and is in contact with the surface (for example, the bottom) of the second substrate SUB2.

The first filling part (FLLa) and a second filling part (FLLb) may be formed integrally.

The second filling part FLLb may contact the lower surface of the second substrate SUB2.

According to some embodiments, the bank layer BNK is also removed from the area where the color filter layer is removed from the non-light emitting area NLA, so that the filling layer FLL contacts the second substrate SUB2, thereby forming a lower surface of the second substrate SUB2, and thereby display quality can be improved by reducing the external light reflectance at the border.

According to a comparative example, when the first color filter CF1, the second color filter CF2, and the third color filter CF3 do not include a color filter opening COP, and the lower surface of the second substrate SUB2 contacts the color filter layer even in the non-light emitting area NLA, the reflectivity between the lower surface of the second substrate SUB2 and the color filter layer is high, so the external light reflectivity from the second substrate SUB2 side was approximately 0.38%, but according to some embodiments including the bank opening BOP, the external light reflectivity measured under the same conditions was approximately 0.26%, confirming that the external light reflectivity decreased by more than approximately 20%.

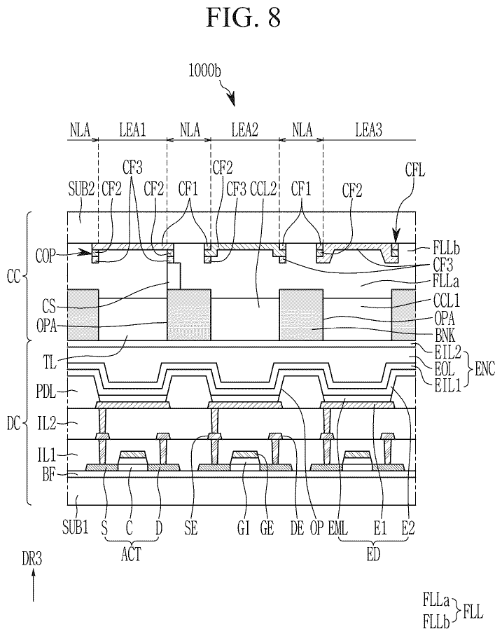

A display device according to some embodiments will be described in more detail with reference to FIG. 8 along with the previously described drawings.

FIG. 8 is a cross-sectional view of the display area of a display device according to some embodiments.

Referring to FIG. 8, the display device 1000b according to some embodiments is mostly the same as the display device 1000 according to the previously described embodiments, but it has a bank layer BNK, a transmission layer TL, and a first color conversion layer CCL1, and the second color conversion layer CCL2 may be formed on the encapsulation part ENC of the display portion DC.

The filling layer FLL may be located between the bank layer BNK, the transmission layer TL, the first color conversion layer CCL1, the second color conversion layer CCL2, the color filter layer, and the second substrate SUB2.

Although not separately indicated, the bank layer BNK may include a portion that overlaps the non-light emitting area NLA and a portion that overlaps the overlapping part of the color filter layer CFL on a plane.

The spacer CS may be located between the bank layer BNK and the overlapping part CFL of the color filter layer, but it is not limited thereto.

According to some embodiments, the portion of the bank layer BNK that overlaps the overlapping part CFL of the color filter layer may be omitted.

The filling layer FLL may contact the second substrate SUB2 (e.g., the bottom surface) through the color filter opening COP of the color filter layer in most areas of the non-light emitting area NLA.

According to some embodiments, the display quality can be improved by reducing the external light reflectance at the lower boundary of the second substrate SUB2 by the filling layer FLL contacting the second substrate SUB2 in the area where the color filter layer has been removed in the non-light emitting area NLA.

According to a comparative example, the first color filter CF1, the second color filter CF2, and the third color filter CF3 do not include the color filter opening COP, so that the second substrate is formed even in the non-light emitting area NLA, when the lower surface of the second substrate SUB2 is in contact with the color filter layer, the reflectance between the lower surface of the second substrate SUB2 and the color filter layer is high, so the external light reflectance on the second substrate SUB2 is approximately 0.38%, but according to some embodiments, the external light reflectance measured under the same conditions was lowered to approximately 0.26%, confirming that the external light reflectance was reduced by approximately 20% or more.

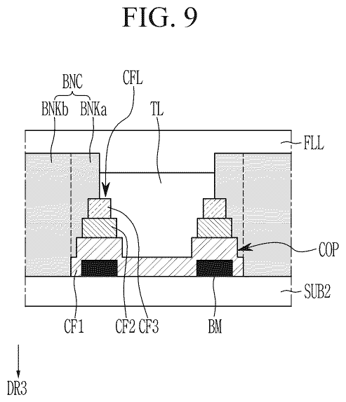

A display device according to some embodiments will be described in more detail with reference to FIG. 9 along with the previously described drawings.

FIG. 9 is a cross-sectional view of a display area of a display device according to some embodiments.

Referring to FIG. 9, the display device according to some embodiments is mostly the same as the display devices 1000, 1000a, and 1000b according to the previously described embodiments, but it has an overlapping portion of the color filter layer CFL and the second substrate SUB2, and it may further include a light blocking layer (BM) positioned between them.

The light blocking layer BM may be located where it overlaps the overlapping part CFL and may be located in the non-light emitting area NLA.

Like the color filter layer, the light blocking layer BM may be removed at most areas of the non-light emitting area NLA—more specifically, at the area where the color filter layer is removed.

The light blocking layer (BM) may include an organic material and may include a pigment such as black carbon.

Although the embodiments of the present invention have been described in detail above, the scope of embodiments according to the present invention are not limited thereto, and various modifications and improvements can be made by those skilled in the art using the basic concepts of the present invention defined in the following claims.

### DESCRIPTION OF SOME OF THE REFERENCE SYMBOLS

110: display panel
1000, 1000a, 1000b: display device
ACT: semiconductor layer
BF: buffer layer
BM: light blocking layer
BNK: bank layer
BOP: bank opening
CC, CC1, CC2: color conversion part
CC3: transmission part
CCL1, CCL2: color conversion layer
CF1, CF2, CF3: color filter
CFL: overlapping part
COP: color filter opening
CS: spacer
DA: display area
DC: display device
ENC: encapsulation part
FLL: filling layer
GI: gate insulating layer
LEA1, LEA2, LEA3: light emitting area
OP: pixel opening
OPA: opening
PA1, PA2, PA3, PX: pixel
PDL: pixel insulating layer
SUB, SUB1, SUB2: substrate
TL: transmission layer

What is claimed is:

1. A display device, comprising:
a display device having a plurality of light emitting areas and a non-light emitting area between adjacent light emitting areas of the plurality of light emitting areas, and
a color conversion part overlapping with the display device,
wherein the color conversion part comprises:
a first substrate including a first surface facing the display device, and
a color filter layer on the first surface of the first substrate and including a plurality of color filters, and
wherein the color filter layer has a color filter opening where the color filter layer is removed at at least a portion of the non-light emitting area.

2. The display device of claim 1, wherein:
the color conversion part further includes a bank layer between the first substrate and the display device, and
the bank layer has an opening corresponding to a light emitting area from among the light emitting areas.

3. The display device of claim 2, wherein:
the bank layer contacts the first surface of the first substrate through the color filter opening.

4. The display device of claim 3, wherein:
at least two of the plurality of color filters overlap in the non-light emitting area to form an overlapping part.

5. The display device of claim 4, wherein:
the color filter opening is defined by an edge of the overlapping part.

6. The display device of claim 4, wherein:
the bank layer includes a first bank part that overlaps the overlapping part and a second bank part that does not overlap the overlapping part, and
the second bank part contacts the first surface of the first substrate in the non-light emitting area.

7. The display device of claim 3, further comprising:
a filling layer between the bank layer and the display device.

8. The display device of claim 2, wherein:
the bank layer is removed from the non-light emitting area to form a bank opening.

9. The display device of claim 8, further comprising:
a filling layer between the first substrate and the display device, and
the filling layer contacts the first surface of the first substrate through the bank opening.

10. The display device of claim 9, wherein:
at least two of the plurality of color filters overlap in the non-light emitting area to form an overlapping part.

11. The display device of claim 10, wherein:
the color filter opening is defined by an edge of the overlapping part.

12. The display device of claim 9, wherein:
the filling layer includes a first filling part overlapping the light emitting area and a second filling part overlapping the non-light emitting area, and
the second filling part contacts the first surface of the first substrate.

13. The display device of claim 2, comprising:
a second substrate, a plurality of light emitting devices on the second substrate, and an encapsulation part on the light emitting device,
wherein the bank layer formed on the encapsulation part further comprises a filling layer between the bank layer and the first substrate.

14. The display device of claim 13, wherein:
the filling layer contacts the first surface of the first substrate through the color filter opening.

15. The display device of claim 14, wherein:
at least two of the plurality of color filters overlap each other in the non-light emitting area to form an overlapping part, and
the color filter opening is defined by an edge of the overlapping part.

16. The display device of claim 15, wherein:
the filling layer includes a first filling part overlapping the light emitting area and a second filling part overlapping the non-light emitting area, and
the second filling part is in contact with the first surface of the first substrate.

17. The display device of claim 1, wherein:
at least two of the plurality of color filters overlap in the non-light emitting area to form an overlapping part, and
a light blocking layer overlaps the overlapping part and is between the color filter layer and the first substrate.

18. A display device, comprising:
a plurality of light emitting areas and a non-light emitting area between adjacent light emitting areas of the plurality of light emitting areas,
a color conversion part overlapping with the display device, and
a filling layer between the display device and the color conversion part,
wherein the color conversion part comprises:
a first substrate including a first surface facing the display device, and
a bank layer between the first substrate and the display device, and
wherein the bank layer or the filling layer contacts the first surface of the first substrate in the non-light emitting area.

19. The display device of claim 18, wherein:
the color conversion part further includes a color filter layer including a plurality of color filters on the first surface of the first substrate, and
the color filter layer has a color filter opening in the non-light emitting area.

20. The display device of claim 19, wherein:
the bank layer or the filling layer contacts the first surface of the first substrate through the color filter opening.
